(19) United States
(12) Patent Application Publication
(10) Pub. No.: US 2018/0248144 A1
(43) Pub. Date: Aug. 30, 2018

(54) FREQUENCY DEPENDENT LIGHT EMITTING DEVICES

(71) Applicant: WAKE FOREST UNIVERSITY, Winston-Salem, NC (US)

(72) Inventor: David L. CARROLL, Winston-Salem, NC (US)

(21) Appl. No.: 15/753,013

(22) PCT Filed: Aug. 25, 2016
(86) PCT No.: PCT/US2016/047459

§ 371 Date: Feb. 15, 2018

Related U.S. Application Data
(60) Provisional application No. 62/206,678, filed on Aug. 18, 2015.

(51) Int. Cl. H01L 51/50; H01L 51/52

(52) U.S. Cl. CPC H01L 51/504; H01L 51/5203; H01L 51/0043; H01L 2251/564; H01L 2251/5376

(57) ABSTRACT

Electroluminescent devices are described herein having structure and design permitting color of emitted light to vary as a function of applied alternating current voltage frequency. Such electroluminescent devices can comprise first and second electrodes and a light emitting assembly between the first and second electrodes, the light emitting assembly including a triplet light emitting layer and a singlet light emitting layer. Emission form the light emitting assembly can vary on the CIE color space as a function of alternating current voltage frequency applied to the first and second electrodes.

### RELATED APPLICATION DATA

The present application claims priority pursuant to 35 U.S.C. § 119(e)(1) to U.S. Provisional Patent Application Ser. No. 62/206,678 filed Aug. 18, 2015 which is incorporated herein by reference in its entirety.

### FIELD

The present invention relates to light emitting devices and, in particular, to light emitting devices demonstrating properties related to alternating current voltage frequencies.

### BACKGROUND

Organic thin film electroluminescent (EL) devices, including organic light emitting devices (OLEDs), typically operate using constant voltage or direct current (DC) power sources. The charge carriers, holes and electrons, are directly injected from high work function and low work function metal electrodes, respectively. Several disadvantages exist with direct current injection architectures. Direct current injection, for example, can precipitate charge accumulation in the recombination zone and large leakage current, resulting in significant exciton quenching. Exicton quenching produces low brightness and series efficiency roll-off. Further, DC driven architectures require power converters and increase device sensitivities to dimensional variations that lead to run away current imperfections. Additionally, in order to achieve effective charge injection, high work function metals are required for anodes, and low work function metals are required for cathodes. Such requirements severely restrict suitable electrode materials for DC devices. Moreover, low work function metals are unstable in air and water, thereby increasing fabrication complexities for DC devices.

### SUMMARY

Electroluminescent devices are described herein which, in some embodiments, offer advantages over prior devices. For example, electroluminescent devices described herein can be driven by alternating current (AC), alleviating charge accumulation by the frequent reversal of applied bias. Moreover, electroluminescent devices described herein can provide emission profiles having CIE color coordinates that vary as a function of AC voltage frequency. The CIE color coordinates can also vary as a function of the composition one or more light emitting layers of the devices.

Briefly, an electroluminescent device described herein, in one aspect, comprises a first electrode and a second electrode, and a light emitting assembly positioned between the first electrode and the second electrode, the light emitting assembly including a triplet light emitting layer and a singlet light emitting layer. Emission from the light emitting assembly can vary on the CIE color space as a function of alternating current voltage frequency applied to the first and second electrodes. In some embodiments, for example, the device exhibits increased emission from the singlet light emitting layer at low alternating current voltage frequencies and increased emission from the triplet light emitting layer at higher alternating current voltage frequency.

An electroluminescent device described herein can also include one or more additional layers or components. For instance, in some cases, an electroluminescent device described herein further comprises a current injection gate positioned between the first electrode and the light emitting assembly or between the second electrode and the light emitting assembly. The current injection gate can comprise a semiconductor layer of electronic structure restricting injected current flow from the first or second electrode through the semiconductor layer as a function of applied alternating current voltage frequency.

Methods of generating light are also described herein. A method of generating light, in some embodiments, comprises providing an electroluminescent device including a first electrode and a second electrode, and a light emitting assembly positioned between the first electrode and the second electrode, the light emitting assembly including a triplet light emitting layer and a singlet light emitting layer. An alternating current voltage is applied to the first and second electrodes to radiatively combine holes and electrons in the light emitting assembly, wherein wavelength of light from the assembly varies according to the frequency of the applied alternating current voltage. For example, the wavelength of light emitted from the assembly can be directly proportional to the frequency of the applied alternating current voltage. Variance of emitted wavelength with alternating current voltage frequency can permit tuning of the electroluminescent device to the desired region of the CIE color space.

These and other embodiments are further described in the detailed description which follows.

### BRIEF DESCRIPTION OF THE DRAWINGS

FIG. 1 illustrates a cross-sectional view of an electroluminescent device according to one embodiment described herein.

FIG. 2 illustrates a cross-sectional view of an electroluminescent device according to one embodiment described herein.

FIG. 3 illustrates a perspective view of an electroluminescent device according to one embodiment described herein.

FIG. 4 illustrates a cross-sectional view of the electroluminescent device of FIG. 3.

FIG. 5 illustrates various electron-hole recombination pathways in a light emitting assembly of an electroluminescent device according to some embodiments described herein.

FIG. 6 illustrates simulated results of magnetic and electric fields at a heterojunction formed by the singlet and triplet light emitting layers at VAC of 60 kHz.

FIG. 7 illustrates the 1931 CIE Chromaticity Diagram coordinates for an electroluminescent device according to one embodiment described herein.

FIG. 8 illustrates photoluminescence decay curves of 474 nm fluorescent emission (top) and 600 nm phosphorescent emission (bottom) of a light emitting assembly according to some embodiments.

FIG. 9(a) illustrates current density versus voltage for an electroluminescent device according to one embodiment described herein.

FIG. 9(b) illustrates luminance versus voltage for an electroluminescent device according to one embodiment described herein.

FIG. 10 is a luminance plot as a function of VAC frequency of an electroluminescent device according to some embodiments described herein.

FIG. 11 illustrate J_{RMS}-frequency characteristics of an electroluminescent device according to some embodiments described herein.

FIG. 12 illustrates a scheme for electron-hole pair generation, transport and recombination between singlet and triplet layers according to some embodiments described herein.

FIG. 13 illustrates electroluminescence intensity versus wavelength for an electroluminescent device according to one embodiment described herein.

FIG. 14 illustrates the blue-red intensity ratio versus alternating current voltage frequency for electroluminescent devices according to some embodiments described herein.

FIG. 15 illustrates normalized electroluminescence intensity versus wavelength for an electroluminescent device according to one embodiment described herein.

FIG. 16 illustrates normalized electroluminescence intensity versus wavelength for an electroluminescent device according to one embodiment described herein.

FIG. 17 illustrates electroluminescence intensity versus wavelength for an electroluminescent device according to one embodiment described herein.

FIG. 18 illustrates electroluminescence intensity versus wavelength for an electroluminescent device according to one embodiment described herein.

FIG. 19 illustrates electroluminescence intensity versus wavelength for an electroluminescent device according to one embodiment described herein.

### DETAILED DESCRIPTION

Embodiments described herein can be understood more readily by reference to the following detailed description, examples and drawings. Elements, apparatus, and methods described herein, however, are not limited to the specific embodiments presented in the detailed description, examples and drawings. It should be recognized that these embodiments are merely illustrative of the principles of the present invention. Numerous modifications and adaptations will be readily apparent to those of skill in the art without departing from the spirit and scope of the invention.

The term “alkyl” as used herein, alone or in combination, refers to a straight or branched chain saturated hydrocarbon radical. In some embodiments, for example, alkyl is C₁₋₂₀ alkyl.

The term “alkenyl” as used herein, alone or in combination, refers to a straight or branched chain hydrocarbon radical containing at least one carbon-carbon double bond. In some embodiments, for example, alkenyl comprises C₂₋₂₀ alkenyl.

The term “aryl” as used herein, alone or in combination, refers to an aromatic ring system radical. Aryl is also intended to include partially hydrogenated derivatives of carbocyclic systems.

The term “heteroalkyl” as used herein, alone or in combination, refers to an alkyl moiety as defined above, having one or more carbon atoms in the chain, for example one, two or three carbon atoms, replaced with one or more heteroatoms, which may be the same or different, where the point of attachment to the remainder of the molecule is through a carbon atom of the heteroalkyl radical.

The term “heteroaryl” as used herein, alone or in combination, refers to an aromatic ring radical with for instance 5 to 7 member atoms, or to an aromatic ring system radical with for instance from 7 to 18 member atoms, containing one or more heteroatoms selected from nitrogen, oxygen, or sulfur heteroatoms, wherein N-oxides and sulfur monoxides and sulfur dioxides are permissible heteroaromatic substitutions; such as, e.g., furanyl, thienyl, thiophenyl, pyrrolyl, imidazolyl, pyrazolyl, triazolyl, tetrazolyl, thiazolyl, oxazolyl, isoxazolyl, oxadiazolyl, thiadiazolyl, isothiazolyl, pyridinyl, pyridazinyl, pyrazinyl, pyrimidinyl, quinolinyl, isoquinolinyl, benzofuranyl, benzothiophenyl, indolyl, and indazolyl, and the like. Heteroaryl is also intended to include the partially hydrogenated derivatives of the heterocyclic systems.

### I. Electroluminescent Devices

An electroluminescent device described herein, in one aspect, comprises a first electrode and a second electrode, and a light emitting assembly positioned between the first electrode and the second electrode, the light emitting assembly including a triplet light emitting layer and a singlet light emitting layer. Emission from the light emitting assembly can vary on the CIE color space as a function of alternating current voltage frequency applied to the first and second electrodes. In some embodiments, for example, the device exhibits increased emission from the singlet light emitting layer at a low alternating current voltage frequencies and increased emission from the triplet light emitting layer at a high alternating current voltage frequency.

It is to be understood that “low” and “high” alternating current voltage frequencies are relative to one another. Further, in some instances, a high alternating current voltage frequency can be 1 to 3 orders of magnitude greater than a low alternating current voltage frequency. For example low alternating current voltage frequency can be less than 1 kHz, and high alternating current voltage frequency can be >1 kHz.

An electroluminescent device described herein can also include one or more additional layers or components. For instance, in some cases, an electroluminescent device described herein further comprises a current injection gate positioned between the first electrode and the light emitting assembly and/or between the second electrode and the light emitting assembly. The current injection gate comprises one or more semiconductor layers of electronic structure restricting injected current flow from the first or second electrode through the semiconductor layer as a function of alternating current voltage frequency. An electroluminescent device described herein may also comprise an electron dopant layer and/or a hole dopant layer. In some embodiments, the electron dopant layer can be positioned proximate the singlet light emitting layer and the hole dopant layer can be positioned proximate the triplet light emitting layer. Thus, an electroluminescent device described herein can have a variety of structures, including an OLED structure or a field-induced electroluminescent structure.

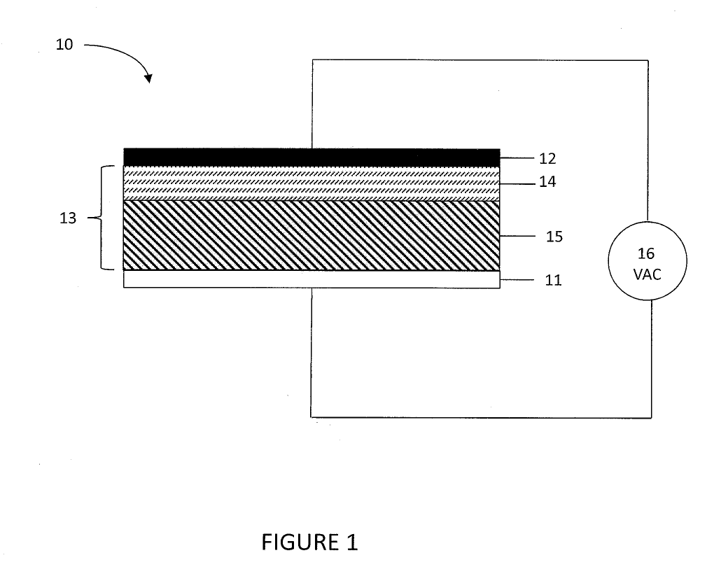

FIG. 1 illustrates a cross-sectional view of an electroluminescent device according to one embodiment described herein. The electroluminescent device (10) illustrated in FIG. 1 comprises a first electrode (11) and second electrode (12) and a light emitting assembly (13) positioned between the first (11) and second (12) electrodes. The light emitting assembly (13) comprises a singlet light emitting layer (14) and a triplet light emitting layer (15). In such embodiments, the electroluminescent device can exhibit an OLED structure. An alternating current voltage (VAC) (16) is applied to the first and second electrodes (11,12).

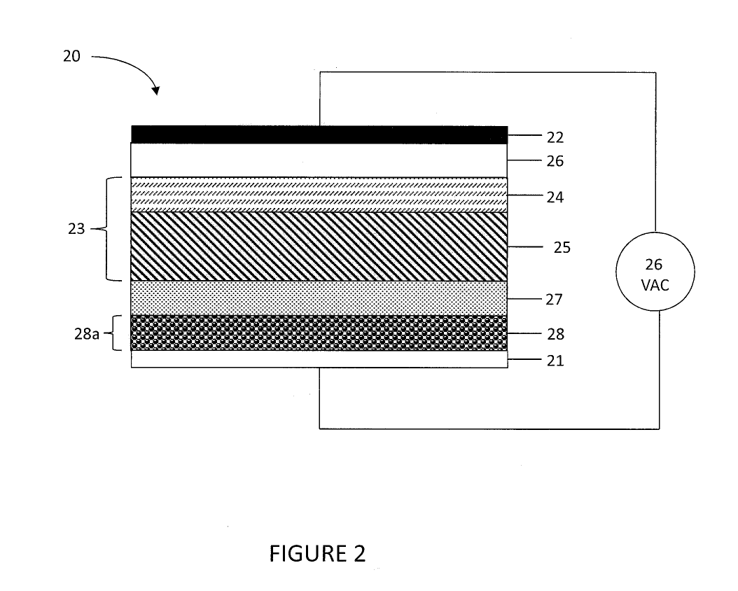

FIG. 2 illustrates a cross-sectional view of an electroluminescent device according to another embodiment described herein. The electroluminescent device (20) illustrated in FIG. 2 comprises a first electrode (21) and second electrode (22) and a light emitting assembly (23) positioned between the first (21) and second (22) electrodes. The light emitting assembly (23) includes a singlet light emitting layer (24) and a triplet light emitting layer (25). Additionally, in the embodiment of FIG. 2, an electron dopant layer (26) is positioned adjacent to the singlet light emitting layer (24), and a hole dopant layer (27) is positioned adjacent to the triplet light emitting layer (23). As discussed further herein, electron and/or hole dopant layers, in some embodiments, can be blended directly into the triplet and/or singlet light emitting layers (24, 25), thereby obviating any requirement for discrete layers of electron donor and/or hole donor materials. Moreover, a current injection gate (28) is positioned between the first electrode (21) and the light emitting assembly (23). The current injection gate (28) can comprise a layer (28a) of semiconductor material of electronic structure restricting injected current flow from the first electrode (21) through the semiconductor layer (28a) as a function of alternating current voltage frequency (26) applied to the first (21) and second (22) electrodes. In an alternative embodiment, the current injection gate (28) can be positioned between the second electrode (22) and the light emitting assembly.

Specific components of electroluminescent devices are now described.

### A. First and Second Electrodes

First and second electrodes can be fabricated from any material not inconsistent with the objectives of the present invention. As described above, materials for the first and second electrodes are not limited to high and low work function metals required for prior DC operating devices. First and second electrodes, for example, can be formed of metal, such as aluminum, nickel, copper, gold, silver, platinum, palladium or other transition metals or alloys thereof. When constructed of a metal or alloy, the first and/or second electrode can be reflective or otherwise non-radiation transmissive. However, in some embodiments, a metal electrode can be of thickness permitting the transmission of radiation.

Alternatively, the first and/or second electrode can be constructed of one or more materials that are radiation transmissive. Radiation transmissive materials can pass electromagnetic radiation provided by light emitting layers described herein without substantial interference or attenuation. Suitable radiation transmissive materials can comprise one or more radiation transmissive conducting oxides. Radiation transmissive conducting oxides can include one or more of indium tin oxide (ITO), gallium indium tin oxide (GITO), aluminum tin oxide (ATO) and zinc indium tin oxide (ZITO). In some embodiments, a radiation transmissive first and/or second electrode is formed of a radiation transmissive polymeric material such as polyanaline (PANI) and its chemical relatives or 3,4-polyethylenedioxythiophene (PEDOT). Further, a radiation transmissive first and/or second electrode can be formed of a carbon nanoparticle layer, such as a carbon nanotube layer, having a thickness operable to at least partially pass visible electromagnetic radiation. An additional radiation transmissive material can comprise a nanoparticle phase dispersed in a polymeric phase.

The first electrode and second electrode can demonstrate the same or different constructions. For example, the first electrode can be non-radiation transmissive and the second electrode radiation transmissive. Moreover, in some embodiments, the first and second electrodes can both be radiation transmissive or non-radiation transmissive. In such embodiments, the first and second electrodes can be fabricated from the same material or different materials. Also, first and second electrodes can have any thickness not inconsistent with the objectives of the present invention. In some embodiments, first and second electrodes have a thickness ranging from 10 nm to 100 μm or more. Additionally, a layer of lithium fluoride (LiF) or lithium oxide (Li₂O) can be positioned between the first and/or second electrode and another layer of the device. For example, a layer of LiF or Li₂O can be positioned between an electron dopant layer and electrode.

### B. Light Emitting Assembly

As described herein, a light emitting assembly is positioned between the first and second electrodes, the light emitting assembly including a singlet light emitting layer and a triplet light emitting layer.

(i) Singlet Light Emitting Layer

In some embodiments, a singlet light emitting layer can include any singlet emitting or fluorescing oligomeric or polymeric species. For example, a singlet light emitting layer can comprise polyfluorene polymers and/or copolymers and/or derivatives thereof. In some embodiments, a singlet light emitting layer comprises polymeric or oligomeric species selected from the group consisting of poly(9,9-di-n-octylfluorenyl-2,7-diyl), poly[(9,9-di-n-octylfluorenyl-2,7-diyl)-alt-(benzo[2,1,3]thiadiazol-4,8-diyl)], poly(9,9-di-n-dodecylfluorenyl-2,7-diyl), poly(9,9-di-n-hexylfluorenyl-2,7-diyl), poly(9,9-di-n-octylfluorenyl-2,7-diyl), poly(9,9-n-dihexyl-2,7-fluorene-alt-9-phenyl-3,6-carbazole), poly[(9,9-dihexylfluoren-2,7-diyl)-alt-(2,5-dimethyl-1,4-phenylene)], poly[(9,9-dihexylfluoren-2,7-diyl)-co-(9-ethylcarbazol-2,7-diyl)], poly[(9,9-dihexylfluoren-2,7-diyl)-co-(anthracen-9,10-diyl)], poly[(9,9-dioctylfluorenyl-2,7-diyl)-co-bithiophene], poly[9,9-bis-(2-ethylhexyl)-9H-fluorene-2,7-diyl], poly((9,9-dihexyl-9H-fluorene-2,7-vinylene)-co-(1-methoxy-4-(2-ethylhexyloxy)-2,5-phenylenevinylene)) (e.g., 90:10 or 95:5 mole ratio), poly(9,9-di-(2-ethylhexyl)-9H-fluorene-2,7-vinylene), poly(9,9-di-n-hexylfluorenyl-2,7-vinylene), poly[(9,9-di-(2-ethylhexyl)-9H-fluorene-2,7-vinylene)-co-(1-methoxy-4-(2-ethylhexyloxy)-2,5-phenylenevinylene)] (e.g., 90:10 or 95:5 mole ratio), PFN-Br, PFN-DOF, PFO-DMP, PHF, PFD, PFH-A-DMP, PFH-EC, PFO-Bpy, PFH-A and mixtures thereof.

Additionally, a conjugated polymeric or oligomeric species of the singlet light emitting layer described herein can comprise a polymer or oligomer including a structural unit of Formula (I):

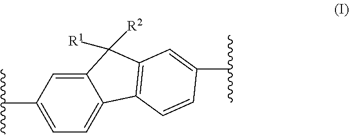

wherein [symbol] represents points of attachment in the polymer or oligomer chain and R¹ and R² are independently selected from the group consisting of hydrogen, alkyl, alkenyl, heteroalkyl and heteroaryl.

In some embodiments, polymer or oligomer of the single light emitting layer can comprise one or more species of poly(naphthalene vinylene)s, poly(naphthalene vinylene) copolymers and/or derivatives thereof. In some embodiments, polymer or oligomer of the singlet light emitting layer comprises one or more species of poly(fluorenylene ethynylene)s, poly(fluorenylene ethynylene) copolymers and/or derivatives thereof. Alternatively, the singlet light emitting layer can include one or more small molecule fluorophores or small molecule fluorescent species. Any small molecule fluorophore or fluorescent species not inconsistent with the objectives of the present invention can be employed. In some embodiments, small molecule fluorophores comprise organic molecules including one or more conjugated systems, such as fused aryl and/or heteroaryl rings. Non-limiting embodiments include xanthene derivatives, cyanine derivatives, squaraine derivatives, acene compounds and derivatives, naphthalene derivatives, coumarin derivatives, anthracene derivatives, pyrene derivatives and oxazine derivatives. For example, fluorescent organic molecules can include various organic dyes. Small molecule fluorophores having any desired emission spectra can be employed. Suitable polymeric and/or small molecule fluorphores can emit in the red, green or blue regions of the electromagnetic spectrum. In some embodiments, small molecule fluorophores can be used alone or in combination with polymeric fluorophores to tune emission of the singlet emission layer.

The singlet light emitting layer can have any thickness not inconsistent with the objectives of the present invention. In some embodiments, the singlet light emitting layer has a thickness of 50 nm to 1 μm.

(ii) Triplet Light Emitting Layer

A triplet light emitting layer described herein can comprise any phosphorescent compound or complex not inconsistent with the objectives of the present invention. In some embodiments, phosphorescent compounds comprise transition metal complexes, including organometallic complexes. For example, a transition metal complex can comprise an iridium or platinum metal center. A phosphorescent transition metal complex, in some embodiments, is tris(2-phenylpyridine)iridium [Ir(ppy)₃] or platinum octaethylporphine (PtOEP). In some embodiments, suitable phosphorescent transition metal complexes for the triplet light emitting layer are selected from Table I:

TABLE I
Transition Metal Complexes of Triplet Emitter Phase

[Os(bpy)₃]²⁺
[Os(phen)₃]²⁺
Ir(ppy)₃
Ir(4,6-dFppy)₂(pic)
Ir(MDQ)₂(acac)
Ir(piq)₂(acac)
[Os(phen)₂(dppee)]²⁺
[Ru(bpy)₃]²⁺
Re(phen)(CO)₃(Cl)
Pt(bhq)₂
Ir(piq)₃
Pt(ppy)₂
Pt(ph-salen)
Ir(btp)₂(acac)
Pt(ONN-t-Bu)Cl
Pt(dphpy)(CO)
Pt(Me₄-salen)
Pt(thpy)₂
Pt(4,6-dFppy)(acac)
Pt(ppy)(CO)(Cl)
Pt(thpy)(CO)(Cl)
Ir(ppy)₂₍CO)(CL)
Pt(qtl)₂
Re(phbt)(CO)₄
Pt(qol)₂
Pd(thpy)₂
Pd(qol)₂
[Pt(bpy)₂]²⁺
[Rh(bpy)₃]³⁺
Ir(btp)₂(acac)
Ir(2-phq)₃
Hex-Ir(phq)₃
Hex-Ir(piq)₃
Ir(fliq)₂(acac)
Ir(2-phq)₂(acac)
Hex-Ir(phy)₂(acac)
Ir(Mphq)₃
Ir(phq)₂tpy
Ir(fbi)₂(acac)
Fac-Ir(ppy)₂Pc
Ir(dpm)PQ₂
Ir(dpm)(piq)₂
Hex-Ir(piq)₂(acac)
Ir(dmpq)₃
Ir(dmpq)₂(acac)

The triplet light emitting layer, in some embodiments, can comprise one or more of Lanthanide and/or Actinide series elements (rare earth emitters) such as erbium, ytterbium, dysprosium, or holmium; metals such as transition metals; metal oxides; metal sulfides; or combinations thereof. In some embodiments, phosphorescent species of the triplet light emitting layer comprise doped yttrium oxide (Y₂O₃) such as Y₂O₃:Eu, Y₂O₃:Zn and Y₂O₃:Ti; doped zinc sulfide such as ZnS:Cu, ZnS:Mn, ZnS:Ga or ZnS:Gd; or doped calcium sulfide such as CaS:Er, CaS:Tb, CaS:Eu or mixtures thereof. In a further embodiment, suitable phosphorescent species include doped zinc oxides, such as ZnO:Eu or doped strontium sulfide such as SrS:Ca, SrS:Mn, SrS:Cu or mixtures thereof. A triplet emitter phase can comprise any mixture of phosphorescent transition metal complexes and other triplet emitting species described herein.

Phosphorescent species can be incorporated into the triplet light emitting layer in any manner not inconsistent with the objectives of the present invention. In some embodiments, for example, one or more phosphorescent species are dispersed throughout a polymeric or oligomeric host or small molecule host. Suitable host material can be selected from Table II:

TABLE II
Host Materials

polyvinyl carbazole (PVK)
poly[(9,9-bis(3′-(N,N-dimethylamino)propyl)-2,7-fluorene)-alt-2,7-(9,9-dioctylfluorene)]
(PFN-DOF)
polyfluorene (PFO)
2,6-bis(3-(9H-Carbazol-9-yl)phenyl)pyridine (26DCzPPy)
9,9-Spirobifluoren-2-yl-diphenylphosphine oxide (SPPO1)
bis(3,5-di(9H-carbazol-9-yl)phenyl) diphenylsilane (SimCP2)
3-(diphenylphosphoryl)-9-(4-(diphenylphosphoryl)phenyl)-9H-carbazole (PPO21)
3,5-bis(3-(9H-carbazol-9-yl)phenyl)pyridine (35DCzPPy)
2,8-Bis(diphenylphosphoryl)dibenzo[b,d]thiophene (PPT)
2,7-Bis(diphenylphosphoryl)spiro[fluorene-7,11′-benzofluorene] (SPPO21)
bis(9 9-spirobifluorene-2-yl)-phenylphosphaneoxide (Dspiro-PO)
4″,4′″-(Phenylphosphoryl)bis(N-1-naphthyl-N-phenyl-1,1′:4′,1″-terphenyl-4-amine) (NP3PPO)
4″,4′″-(Phenylphosphoryl)bis(N-1-naphthyl-N-phenyl-1,1′:4′,1″4″1″-quatterphenyl-4-amine)
(NP4PPO)
9-(3,5-bis(diphenylphosphoryl)phenyl)-9H-carbazole (CzPO2)
Ph-metacresol purple (ph-MCP)
G3-tCbz (CAS 472960-35-3)
(9-(3-(9 H-carbazol-9-yl)phenyl)-9 H-carbazol-3-yl)-diphenylphosphine oxide (mCPPO1)
3-(3-(9H-Carbazol-9-yl)phenyl)benzofuro[2,3-b]pyridine (PCz-BFP)
9-(3-(dibenzo[b,d]furan-2-yl)phenyl)-9H-carbazole (CzDBF)
DV-CBP (C40H28N2)
1,3-Bis(carbazol-9-yl)benzene (MCP)
Tricresyl phosphate(TCP)
Tris(4-carbazoyl-9-ylphenyl)amine (TCTA)
4,4′-bis(9-carbazolyl)-biphenyl (CBP)
4,4′-bis(9-carbazolyl)-2,2′dimethyl-biphenyl (CDBP)
2,7-bis(carbazol-9-yl)-9,9-dimethylfluorene (DMFL-CBP)
9,9′,9″,9′″-(9,9′-Spirobi[9H-fluorene]-2,2′,7,7′-tetrayl)tetrakis-9H-carbazole (Spiro-CBP)
9,9-bis(4-(carbazol-9-yl)-phenyl)fluorene (FL-2CBP)
2,7-Bis(carbazol-9-yl)-9,9-spirobifluorene (Spiro-2CBP)
bis(2-methylphenyl)diphenylsilane (UGH-1)
p-bis(triphenylsilyl)benzene (UGH-2)
1,3-bis(triphenylsilyl)benzene (UGH-3)
Bis(4-N,N-diethylamino-2-methylphenyl)-4-methylphenylme (MPMP)
2,7-Bis(9-carbazolyl)-9,9-dioctylfluorene (DOFL-CBP)
4,4″-bis(triphenylsilanyl)-(1,1′,4′,1″)-terphenyl (BST)
Disodium bis(2-sulfonatostyryl)biphenyl (BSB)
9-(4-tert-butylphenyl)-3,6-bis(triphenylsilyl)-9H-carbazole (CzSi)
9-(4-tert-butylphenyl)-3,6-ditrityl-9H-carbazole (CzC)
DFC (CAS 871018-07-4)
[3,5-Di(9H-carbazol-9-yl)phenyl]triphenylsilane (SimCP)
4,4,8,8,-12,12-hexa-p-tolyl-4H-8H-12H-12C-aza-dibenzo[;4,4,8,8,-12,12-hexa-p-tolyl-4H-8H-
12H-12C-aza-dibenzo[cd,Mn]pyrene (FATPA)
4,7-di(9H-carbazol-9-yl)-1,10-phenanthroline (BUPH1)
Diarylmethylene-bridged 4,4′-(bis(9-carbazolyl))biphenyl (BCBP)
3,6-bis(carbazol-9-yl)-9-(2-ethyl-hexyl)-9H-carbazole (TCz1)
9-phenyl-3,6-bis-[1,1′;3′1″]terphenyl-5′-yl-9H-carbazole (CzTP)
2,8-di(9H-carbazol-9-yl)dibenzo[b,d]thiophene (DCzDBT)
10-(4′-(diphenylamino)biphenyl-4-yl)acridin-9(10H)-one (ADBP)
2,7-bis(diphenylphosphoryl)-9,9′-spirobi[fluorene] (SPPO13)
N,N-dicarbazolyl-1,4-dimethene-benzene (DCB)
bathocuproine (BCPO)
2,7-Bis(diphenylphosphoryl)-9-(4-diphenylaMino)phenyl-9′-phenyl-fluorene (POAPF)
2,7-bis(diphenylphosphoryl)-9-phenyl-9H-carbazole (PPO27)
3-(carbazol-9-ylmethyl)-3-methyloxetane (PCMO)
4-chloro-2-methylphenol (PCOC)
CzPO2G3-tCbz
CNBzlm
diphenyl-4-triphenylsilylphenyl-phosphine oxide (TSPO1)
9,9-spirobifluoren-4-yl-diphenyl-phosphineoxide (SPPO11)
9-(8-(diphenylphosphoryl)dibenzo[b,d]furan-2-yl)-9H-carbazole (DFCzPO)
9,9-bis(9-methylcarbazol-3-yl)-4,5-diazafluorene (MCAF)
2-(benzothiazol-2-yl)phenol or 2,2′-bistriphenylenyl (BTP1)
Bis[2-(diphenylphosphino)phenyl]ether oxide (DPEPO)
Poly[9-sec-butyl-2,7-difluoro-9H-carbazole] (2,7-F-PVF)
9-(4-(9H-pyrido[2,3-b]indol-9-yl)phenyl)-9H-3,9′-bicarbazole (pBCb2Cz)
2,6-Di(9H-carbazol-9-yl)pyridine (PYD-2Cz)
3-(4-(9H-Carbazol-9-yl)phenyl)-9-(4,6-diphenyl-1,3,5-triazin-2-yl)-9H-carbazole (CPCBPTz)
4,6-Bis(3-(9H-carbazol-9-yl)phenyl)pyrimidine (46DCzPPM)
9-(3,5-Di(triphenylen-2-yl)phenyl)-9H-carbazole (DTP-mCP)
9,9′-Diphenyl-9H,9′H-3,3′-bicarbazole (BCzPh)
9,9′-(Oxybis([1,1′-biphenyl]-4′,3-diyl))bis(9H-carbazole) (CBBPE)
9,9′-Diphenyl-9H,9′H-3,3′-bicarbazole-6-carbonitrile (BCzSCN)
9-(3-(3,5-Di(pyridin-2-yl)-1H-1,2,4-triazol-1-yl)phenyl)-9H-carbazole (m-cbtz)
4-(4,6-Bis[12-phenylindolo[2,3-a]carbazol-11(12H)-yl]-1,3,5-triazin-2-yl)-benzonitrile
(BBICT)

Phosphorescent species can be present in the triplet light emitting layer in any amount not inconsistent with the objectives of the present invention. In some embodiments, one or more phosphorescent species are present in the triplet light emitting layer in an amount selected from Table III, where weight percent values are based on the total weight of the triplet light emitting layer.

TABLE III
Wt. % of Phosphorescent Species in Triplet Light Emitting Layer
0.01-25
0.05-30
0.1-15
0.1-10
0.5-5
1-30
1-10
1-5
1-3
1.5-30
2-30
2-10
2-5
3-30
4-30
5-30
10-30

In some embodiments, a transition metal complex is operable to participate in energy/charge transfer with one or more other species of the triplet light emitting layer. For instance, a phosphorescent transition metal complex of the triplet emitter phase can be operable to receive energy from the polymeric or oligomeric host, such as through resonant energy transfer. Resonant energy transfer can include Förster energy transfer and/or Dexter energy transfer. In some embodiments, phosphorescent transition metal complex is operable to receive triplet excited states from the singlet emitter polymeric or oligomeric host for subsequent radiative relaxation of the received triplet excited states to the ground state. Moreover, in some embodiments, a phosphorescent transition metal complex of the triplet emitter phase is also operable to receive singlet excited states from the singlet emitter polymeric or oligomeric host for subsequent radiative relaxation of the received singlet excited states to the ground state. In some embodiments, relaxation of the received singlet excited state occurs through a phosphorescent pathway. Alternatively, singlet emission from the polymeric or oligomeric host can be represented in the emission profile of the triplet light emitting layer along with the triplet emission from the phosphorescent species.

The triplet light emitting layer, in some embodiments, further comprises a nanoparticle phase. For example, nanoparticles can be dispersed substantially uniformly throughout the triplet light emitting layer. Alternatively, the nanoparticle phase is heterogeneously distributed in the triplet light emitting layer. In some embodiments, nanoparticles are present in the triplet light emitting layer in an amount selected from Table IV, where the amount is based on the total weight of the triplet light emitting layer.

```
TABLE IV
Weight Percent of Nanoparticle Phase
Nanoparticle (wt. %)
0.001-20
0.01-15
0.1-10
0.5-5
  1-4
0.01-3
0.01-0.5
0.01-0.3
0.01-0.2
  0.01-0.15
```

In some embodiments, nanoparticles are present in the triplet light emitting layer in an amount below the percolation threshold.

A nanoparticle phase can comprise any nanoparticles not inconsistent with the objectives of the present invention. In some embodiments, nanoparticles of the nanoparticle phase comprise carbon nanoparticles including, but not limited to, fullerenes, carbon nanotubes, carbon quantum dots, graphene particles or mixtures thereof. Fullerenes suitable for use in the nanoparticle phase, in one embodiment, can comprise 1-(3-methoxycarbonyl)propyl-1-phenyl(6,6)C₆₁ (PCBM), higher order fullerenes (C₇₀ and higher) and endometallofullerenes (fullerenes having at least one metal atom disposed therein). Carbon nanotubes for use in the nanoparticle phase can comprise single-walled nanotubes (SWNT), multi-walled nanotubes (MWNT), cut nanotubes, nitrogen and/or boron doped carbon nanotubes or mixtures thereof. Inorganic nanoparticles are also suitable for use in the nanoparticle phase. For example, the nanoparticle phase can include metal nanoparticles such as gold nanoparticles, silver nanoparticles, copper nanoparticles, nickel nanoparticles and/or other transition metal nanoparticles. Inorganic nanoparticles can comprise quantum dots or inorganic semiconductor nanoparticles such as IIB/VIA nanoparticles, IIIA/VA nanoparticles, IVA/VIA nanoparticles or mixtures thereof. Groups of the Periodic Table described herein are identified according to the CAS designation. Semiconductor nanoparticles, in some embodiments, are selected from the group consisting of PbS, PbSe, CdTe, CdS, InP, GaAs and mixtures thereof. Inorganic nanoparticles can demonstrate a variety of shapes, including wires, rods, and spheres or dots.

The triplet light emitting layer can have any thickness not inconsistent with the objectives of the present invention. In some embodiments, the singlet light emitting layer has a thickness of 50 nm to 1 μm or more.

As described above, the singlet light emitting layer and triplet light emitting layer can be discrete layers. Alternatively, the singlet light emitting layer and triplet light emitting layer can be blended into a single layer. For example, materials forming the singlet light emitting layer and materials forming the triplet light emitting layer can be blended together to provide the light emitting assembly. In such embodiments, discontinuous singlet emitting regions and triplet emitting regions may form.

### C. Current Injection Gate

As described herein, an electroluminescent device can comprise a current injection gate positioned between the first electrode and the light emitting assembly and/or between the second electrode and the light emitting assembly. In some embodiments, the current injection gate comprises a semiconductor layer of electronic structure restricting injected current flow from the first or second electrode through the semiconductor layer as a function of alternating current voltage frequency. For example, injected current flow from the first or second electrode through the semiconductor layer can decrease with increasing frequency of the applied alternating current voltage. Alternatively, current from the first or second electrode, in some embodiments, increases with increasing frequency of the applied alternating current voltage.

Semiconducting materials demonstrating this frequency dependent restriction of injected current from the first or second electrode can serve as the current injection gate in the electroluminescent device architecture. Suitable gate semiconductor materials can comprise inorganic semiconductors and organic semiconductors. For example, in some embodiments, inorganic gate semiconductors comprise transition metal oxides, including titanium oxide or zinc oxide. In some embodiments, inorganic gate semiconductors are selected from Tables V and VI.

TABLE V
Inorganic Gate Semiconductors

| | |
|---|---|
| Silicon | Si |
| Germanium | Ge |
| Gray tin, α-Sn | Sn |
| Silicon carbide, 3C—SiC | SiC |
| Silicon carbide, 4H—SiC | SiC |
| Silicon carbide, 6H—SiC | SiC |
| Sulfur, α-S | S₈ |
| Gray selenium | Se |
| Tellurium | Te |
| Boron nitride, cubic | BN |
| Boron nitride, hexagonal | BN |
| Boron nitride, nanotube | BN |
| Boron phosphide | BP |
| Boron arsenide | BAs |
| Boron arsenide | B₁₂As₂ |
| Aluminium nitride | AlN |
| Aluminium phosphide | AlP |
| Aluminium arsenide | AlAs |
| Aluminium antimonide | AlSb |
| Gallium nitride | GaN |
| Gallium phosphide | GaP |
| Gallium arsenide | GaAs |
| Gallium antimonide | GaSb |
| Indium nitride | InN |
| Indium phosphide | InP |
| Indium arsenide | InAs |
| Indium antimonide | InSb |
| Cadmium selenide | CdSe |
| Cadmium sulfide | CdS |
| Cadmium telluride | CdTe |
| Zinc oxide | ZnO |
| Zinc selenide | ZnSe |
| Zinc sulfide | ZnS |
| Zinc telluride | ZnTe |
| Cuprous chloride | CuCl |
| Copper sulfide | Cu₂S |
| Lead selenide | PbSe |
| Lead(II) sulfide | PbS |
| Lead telluride | PbTe |
| Tin sulfide | SnS |
| Tin sulfide | SnS₂ |
| Tin telluride | SnTe |
| Lead tin telluride | PbSnTe |
| Thallium tin telluride | Tl₂SnTe₅ |
| Thallium germanium telluride | Tl₂GeTe₅ |
| Bismuth telluride | Bi₂Te₃ |
| Cadmium phosphide | Cd₃P₂ |
| Cadmium arsenide | Cd₃As₂ |
| Cadmium antimonide | Cd₃Sb₂ |
| Zinc phosphide | Zn₃P₂ |
| Zinc arsenide | Zn₃As₂ |
| Zinc antimonide | Zn₃Sb₂ |
| Titanium dioxide, anatase | TiO₂ |
| Titanium dioxide, rutile | TiO₂ |
| Titanium dioxide, brookite | TiO₂ |
| Copper(I) oxide | Cu₂O |
| Copper(II) oxide | CuO |
| Uranium dioxide | UO₂ |
| Uranium trioxide | UO₃ |
| Bismuth trioxide | Bi₂O₃ |
| Tin dioxide | SnO₂ |
| Barium titanate | BaTiO₃ |
| Strontium titanate | SrTiO₃ |
| Lithium niobate | LiNbO₃ |
| Lanthanum copper oxide | La₂CuO₄ |
| Lead(II) iodide | PbI₂ |
| Molybdenum disulfide | MoS₂ |
| Gallium selenide | GaSe |
| Tin sulfide | SnS |
| Bismuth sulfide | Bi₂S₃ |
| Gallium manganese arsenide | GaMnAs |
| Indium manganese arsenide | InMnAs |
| Cadmium manganese telluride | CdMnTe |
| Lead manganese telluride | PbMnTe |
| Lanthanum calcium manganate | La_{0.7}Ca_{0.3}MnO₃ |
| Iron(II) oxide | FeO |
| Nickel(II) oxide | NiO |
| Europium(II) oxide | EuO |
| Europium(II) sulfide | EuS |
| Chromium(III) bromide | CrBr₃ |
| Copper indium selenide, CIS | CuInSe₂ |
| Silver gallium sulfide | AgGaS₂ |
| Zinc silicon phosphide | ZnSiP₂ |
| Arsenic sulfide | As₂S₃ |
| Platinum silicide | PtSi |
| Bismuth(III) iodide | BiI₃ |
| Mercury(II) iodide | HgI₂ |
| Thallium(I) bromide | TlBr |
| Silver sulfide | Ag₂S |
| Iron disulfide | FeS₂ |
| Copper zinc tin sulfide, CZTS | Cu₂ZnSnS₄ |

TABLE VI
Inorganic Gate Semiconductors

| | |
|---|---|
| Silicon-germanium | Si₁₋ₓGeₓ |
| Aluminium gallium arsenide | AlₓGa₁₋ₓAs |
| Indium gallium arsenide | InₓGa₁₋ₓAs |
| Indium gallium phosphide | InₓGa₁₋ₓP |
| Aluminium indium arsenide | AlₓIn₁₋ₓAs |
| Aluminium indium antimonide | AlₓIn₁₋ₓSb |
| Gallium arsenide nitride | GaAsN |
| Gallium arsenide phosphide | GaAsP |
| Gallium arsenide antimonide | GaAsSb |
| Aluminium gallium nitride | AlGaN |
| Aluminium gallium phosphide | AlGaP |
| Indium gallium nitride | InGaN |
| Indium arsenide antimonide | InAsSb |
| Indium gallium antimonide | InGaSb |
| Aluminium gallium indium phosphide | AlGaInP |
| Aluminium gallium arsenide phosphide | AlGaAsP |
| Indium gallium arsenide phosphide | InGaAsP |
| Indium gallium arsenide antimonide | InGaAsSb |
| Indium arsenide antimonide phosphide | InAsSbP |
| Aluminium indium arsenide phosphide | AlInAsP |
| Aluminium gallium arsenide nitride | AlGaAsN |
| Indium gallium arsenide nitride | InGaAsN |
| Indium aluminium arsenide nitride | InAlAsN |
| Gallium arsenide antimonide nitride | GaAsSbN |
| Gallium indium nitride arsenide | GaInNAsSb |
| antimonide | |
| Gallium indium arsenide antimonide | GaInAsSbP |
| phosphide | |
| Cadmium zinc telluride, CZT | CdZnTe |
| Mercury cadmium telluride | HgCdTe |
| Mercury zinc telluride | HgZnTe |
| Mercury zinc selenide | HgZnSe |
| Copper indium gallium selenide, CIGS | Cu(In,Ga)Se₂ |

Moreover, organic gate semiconductors can comprise small molecule semiconductors including acene and/or acene derivatives such as anthracene, tetracene, pentacene, hexacene, heptacene or rubrene. In some embodiments, small molecule gate semiconductor is selected from Table VII.

TABLE VII
Small Molecule Gate Semiconductors

2,7-alkyl[1]benzothieno[3,2-b][1]benzothiophene (C8-BTBT)
2,9-alkyl-dinaphtho[2,3-b:2′,3′-f]thieno[3,2-b]thiophene (C10-DNTT)
N,N-1H,1H-perfluorobutyldicyanoperylene-carboxydiimide (PDIF-CN₂)
Sexithiophene (6T)
poly[9,9′dioctyl-fluorene-co-bithiophene] (F8T2)
polytriarylamine (PTAA)
poly-2,5-thienylene vinylene (PVT)
α,ω-dihexylquinquethiophene (DH-5T)
α,ω-dihexylsexithiophene (DH-6T)
perfluorocopperphthalocyanine (FPcCu)
3′,4′-dibutyl-5,5″-bis(dicyanomethylene)-5,5″-dihydro-2,2′:5′,-2″-
terthiophene (QM3T)
α,ω-diperfluorohexyloligothiophene (DFH-nT)
2,7-[bis(5-perfluorohexylcarbonylthien-2-yl)]-4H-cyclopenta-
[2,1-b:3,4-b′]-dithiophen-4-one (DFHCO-4TCO)
Poly[bisbenzimidazobenzophenanthroline] (BBB)
α,ω-diperfluorophenylquaterthiophene (FTTTTF)
dicyanoperylene-bis[dicarboximide] (DPI-CN)
naphthalene tetracarboxylic diimide (NTCDI)
Tetracene
Anthracene
Tetrathiafulvalene (TTF)
Poly(3-alkythiophene)
Dithiotetrathiafulvalene (DT-TTF)
Cyclohexylquaterthiophene (CH4T)

Additionally, organic gate semiconductor can comprise one or more conjugated polymeric materials including polyacetylene, polyacetylene derivatives, poly(9,9-di-octylfluorene-alt-benzothiadiazole) (F8BT), poly[2-methoxy-5-(2-ethylhexyloxy)-1,4-phenylenevinylene] [MEH-PPV], P3HT, poly(3,4-ethylenedioxythiophene) (PEDOT), PEDOT:PSS or mixtures thereof. In some embodiments, gate semiconductor is formed of carbon nanoparticles, such as those listed in Table VIII.

TABLE VIII
Carbon Nanoparticle Gate Semiconductors

Fullerene-C₆₀
(6,6)-phenyl-C₆₁butyric acid methyl ester (PC₆₁BM)
(6,6)-phenyl-C₇₁butyric acid methyl ester (PC₇₁BM)
(6,6)-phenyl-C₆₁methyl-hexanoate (PC₆₁HM)
(5,6)-fullerene-C₇₀
(6,6)-phenyl-C₇₁hexanoic acid methyl ester (PC₇₁HM)

Gate semiconductors can be intrinsic or doped. Further, suitable inorganic and/or organic gate semiconductors can demonstrate a bandgap of at least 2 eV or at least 3 eV. In some embodiments, gate semiconductor material has a bandgap of 2 to 4 eV or 2.5 to 3.5 eV.

A semiconductor layer of a current injection gate can have any thickness not inconsistent with the objectives of the present invention. In some embodiment, a gate semiconductor layer has a thickness selected from Table IX.

```
TABLE IX
Current Injection Gate Semiconductor Layer Thickness (nm)
  1-500
  5-100
10-75
15-50
20-40
```

In further embodiments, a current injection gate having frequency dependent behavior can be a composite formed of organic and inorganic components. For example, a current injection gate composite can comprise inorganic particles dispersed in a polymeric matrix. In some embodiments, one or more ceramic particles (e.g. metal carbides, metal oxides, metal carbonitrides, metal nitrides, metal oxynitrides and/or metal oxycarbonitrides) can be dispersed in a polymeric matrix to provide a current injection gate exhibiting a frequency dependent restriction of injected current from the first or second electrode. In some embodiment, polymer of the matrix is conjugated or semiconducting. A current injection gate composite can employ up to about 90 wt % inorganic particles with the balance polymeric matrix. In some embodiments, a current injection gate comprises 15-75 wt. % inorganic particles with the balance polymeric matrix. Suitable inorganic particles and conjugated polymer for the current injection gate composite are described in this Section C. Inorganic particles for the composite current injection gate can have any average particle size not inconsistent with the objectives of the present invention. For example, in some embodiments, the inorganic particles are nanoparticles having an average size less than 1 μm. In some embodiments, the inorganic particles have an average size from 10 μm to 500 μm. Alternatively, the inorganic particles can have an average size greater than 1 μm. A current injection gate composite, in some embodiments, has a thickness selected from Table IX.

### D. Electron and Hole Dopant Layers

As described herein, an electroluminescent device can further comprise an electron dopant layer and/or hole dopant layer. When present, the electron dopant layer can be positioned proximate the singlet light emitting layer and the hole dopant layer can be positioned proximate the triplet emitting layer.

Electron and hole dopant layers can be formed of semiconducting polymer and/or conjugated small molecule. In some embodiments, for example, electron and hole dopant layers are selected from Table X.

TABLE X
Electron and Hole Dopant Materials

| Electron Dopant Material | Hole Dopant Material |
|---|---|
| 3,3′-[5′-[3-(3- | Poly(3-hexylthiophene-2,5-diyl) |
| Pyridinyl)phenyl][1,1′:3′,1″- | |
| terphenyl]-3,3″-diyl]bispyridine | |
| 1,3,5-Tris(1-phenyl- | Poly(4-butylphenyl-diphenyl-amine) |
| 1H-benzimidazol-2-yl)benzene | or poly[N,N′-bis(4-butylphenyl)- |
| | N,N′-bis(phenyl)benzidine] |
| Bathophenanthroline | poly(9,9-dioctyl-fluorene-co-N-(4- |
| | butylphenyl)-diphenylamine) |
| Bathocuproine | 2,3,5,6-Tetrafluoro-7,7,8,8- |
| | tetracyanoquinodimethane |
| | poly(9,9-di-ndodecylfluorenyl- |
| | 2,7-diyl) |

In some embodiments, an electron dopant layer or hole dopant has a thickness of 10 nm to 100 nm. Moreover, an electron and/or hole dopant layer can have a thickness less than 10 nm or greater than 100 nm.

### E. Dielectric Layers

As described herein, an electroluminescent device can comprise one or more dielectric or electrically insulating layers positioned between the first and/or second electrode and the light emitting assembly. A dielectric layer can comprise any insulating material not inconsistent with the objectives of the present invention. For example, in some embodiments, a dielectric layer comprises one or more inorganic oxides. In some embodiments, an inorganic oxide comprises a transition metal oxide, alumina (Al₂O₃), silica (SiO₂) or mixtures thereof.

In some cases, a dielectric layer comprises one or more polymeric materials. Suitable polymers for use in a dielectric layer comprise fluorinated polymers such as polyvinylidene fluoride (PVDF), poly(vinylidene fluoride-trifluoroethylene) (PVDF-TrFE), poly(vinyl fluoride) (PVF), polytetrafluoroethylene (PTFE), perfluoropropylene, polychlorotrifluoroethylene (PCTFE), or copolymers and combinations thereof. A dielectric polymeric material can also comprise one or more polyacrylates such as polyacrylic acid (PAA), poly(methacrylate) (PMA), poly(methylmethacrylate) (PMMA), or copolymers and combinations thereof. In some instances, a dielectric polymeric material comprises polyethylenes, polypropylenes, polystyrenes, poly(vinylchloride)s, polycarbonates, polyamides, polyimides, or copolymers and combinations thereof. Polymeric dielectric materials described herein can have any molecular weight (M_{w}) and polydispersity not inconsistent with the objectives of the present invention.

Additionally, a dielectric layer can further comprise nanoparticles. In some embodiments, nanoparticles of a dielectric layer can comprise any nanoparticles described in Section I herein. In some cases, nanoparticles can be present in the dielectric layer in an amount less than about 0.5 weight percent or less than about 0.1 weight percent, based on the total weight of the dielectric layer. In some embodiments, nanoparticles are present in the dielectric layer in an amount ranging from about 0.01 weight percent to about 0.1 weight percent.

Moreover, in some embodiments, an electrically insulating material of a dielectric layer is selected based on its dielectric constant and/or breakdown voltage. For instance, in some embodiments, an insulating material of a dielectric layer has a high dielectric constant and/or a high breakdown voltage. In addition, a dielectric layer described herein can have any thickness not inconsistent with the objectives of the present invention.

Components of an electroluminescent device described herein, including the first and second electrodes, singlet light emitting layer, triplet light emitting layer, current injection gate, nanoparticle phase(s), electron dopant layer, hole dopant layer, first dielectric layer and/or second dielectric layer can be combined in any manner not inconsistent with the objectives of the present invention.

Additionally, electroluminescent devices having an architecture described herein, in some embodiments, demonstrate power efficiencies, current efficiencies and luminance values of Table XI. Further, power and current efficiencies and luminance values listed in Table XI, in some embodiments, can be achieved without the use of light out-coupling structures traditionally applied to light emitting devices to enhance light extraction.

TABLE XI
Power and Current Efficiencies and Luminance

| Power Efficiency (lm/W) | Current Efficiency (cd/A) | Luminance (cd/m²) |
|---|---|---|
| ≥50 | ≥20 | 1500-8000 |
| ≥80 | ≥30 | 2000-7000 |
| ≥100 | ≥40 | 4000-6000 |
| ≥110 | 15-50 | |
| ≥120 | 15-40 | |
| 50-150 | | |
| 80-130 | | |
| 80-120 | | |
| 100-150 | | |

Moreover, an electroluminescent device having an architecture described herein can be tuned to display electroluminescent emission having any desired color temperature (2000-8000K), such as 2000-5000K. Moreover, electroluminescent devices described herein can demonstrate a color rendering index (CRI) of at least 80 or 85.

### II. Methods of Generating Light

Methods of generating light are also described herein. A method of generating light, in some embodiments, comprises providing an electroluminescent device including a first electrode and a second electrode, and a light emitting assembly positioned between the first electrode and the second electrode, the light emitting assembly including a triplet light emitting layer and a singlet light emitting layer. An alternating current voltage is applied to the first and second electrodes to radiatively combine holes and electrons in the light emitting assembly, wherein wavelength of light from the assembly varies according to the frequency of the applied alternating current voltage. For example, the wavelength of light emitted from the assembly can be directly proportional to the frequency of the applied alternating current voltage. While not wishing to be bound by any theory, it is believed that emission from the singlet light emitting layer dominates at low frequencies. As frequency increases, the triplet light emitting layer begins to dominate, thereby red-shifting the emission from the device. Such is evidenced in the examples and data presented herein.

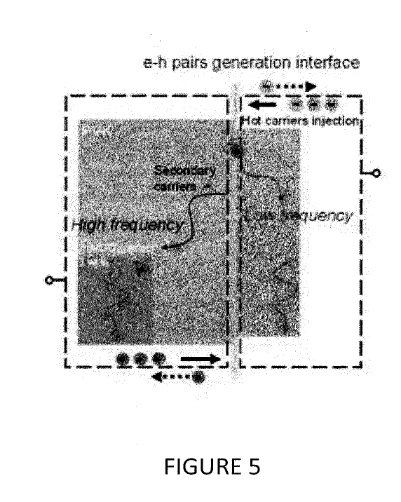

In some embodiments, a heterojunction is formed between the singlet and triplet light emitting layers. For example, the singlet light emitting layer can exhibit n-type character while the triplet light emitting layer exhibits p-type character, thereby forming a p-n junction. At different driving frequencies (VAC), there is more or less time for carrier accumulation at this interface. However, in some embodiments, the current injection gate, when present, allows only for field-generated carrier injection into the emitting volume, while at lower frequencies the gate allows for direct injection from the contacts. Nevertheless, both conditions result in drifting charge heading toward the interface or junction of the singlet and triplet light emitting layers. Diffusive electrons and holes are transferred to the heterointerface in the positive cycle of AC electric field and drifted along the opposite direction in reversed bias. Therefore, time-dependent electric field generates a 2D interfacial magnetic field at the triplet layer/singlet layer heterointerface based on Maxwell's equations. Meanwhile, the heterointerface is also playing the role of an electron-hole pair recombination zone for hot carrier injection as shown in energy level diagram in FIG. 5.

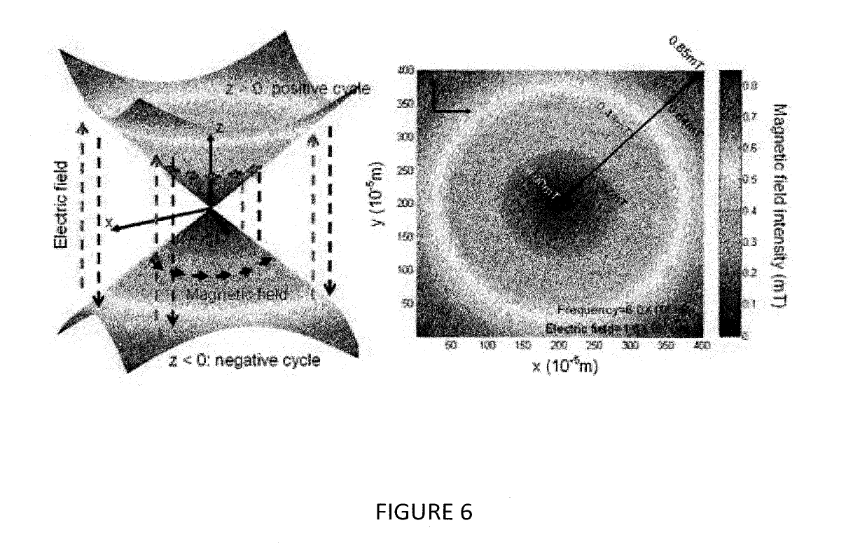

These electron-hole pairs move in the applied electric field, but also experience the induced magnetic field. In an ideal case, pixel dimension is 4 mm×4 mm, significantly larger than its thickness (˜300 nm)—so it is reasonable to ignore fringing effects (infinite area parallel plate capacitor assumption). Via engaging a high frequency driving (60,000 Hz) and strong AC electrical field (1.6×10⁸V/m), temporal and spatial characteristics of the internal magnetic field are shown in FIG. 6. The upper and lower half plane represent the opposite “clock directions” of magnetic field in the positive and negative halves of an AC cycle. The amplitude of the magnetic field is estimated to be approximately 0.85 mT.

When this internal AC magnetic field is of the same order as the nuclear hyperfine field (˜1 mT), intersystem crossing (ISC) suppression can occur and induce singlet-spin electron-hole pair accumulation. A large number of secondary carriers will be produced in singlet layer through the magnetically-mediated dissociation of the electron-hole pairs. The secondary charges are diffused to nearby triplet emitter sites (e.g. transition metal complex), which yields decay of triplet-state excitons as shown in FIG. 5.

No significant position shift of recombination zone in the device is generally seen. Therefore, in the low frequency driving regime (50 Hz˜1,000 Hz), hot carrier injection can be the main mechanism for fluorescent excitons in singlet layer. In a high frequency regime (e.g. 30,000 Hz˜70,000 Hz), the high intensity AC magnetic field at the singlet-triplet layer interface greatly populates singlet-excited e-h pairs via ISC suppression, which leads to secondary carriers. The secondary carriers exist in form of bonded electrons in the singlet polymer matrix, more specifically with halogen atoms of the polymer which are strong electron acceptors. The charged halogens ions, such as Br⁻, can significantly improve the carrier diffusion length, resulting in movable negative charges across interfacial energy barrier. Consequently, the secondary carriers are transferred to triplet emitter sites for phosphorescent emission. For the same reason, the charged movable Br ions greatly facilitate magnetic-field current even in very subtle magnetic intensity with non-ionized polymer which normally needs over hundreds of mT.

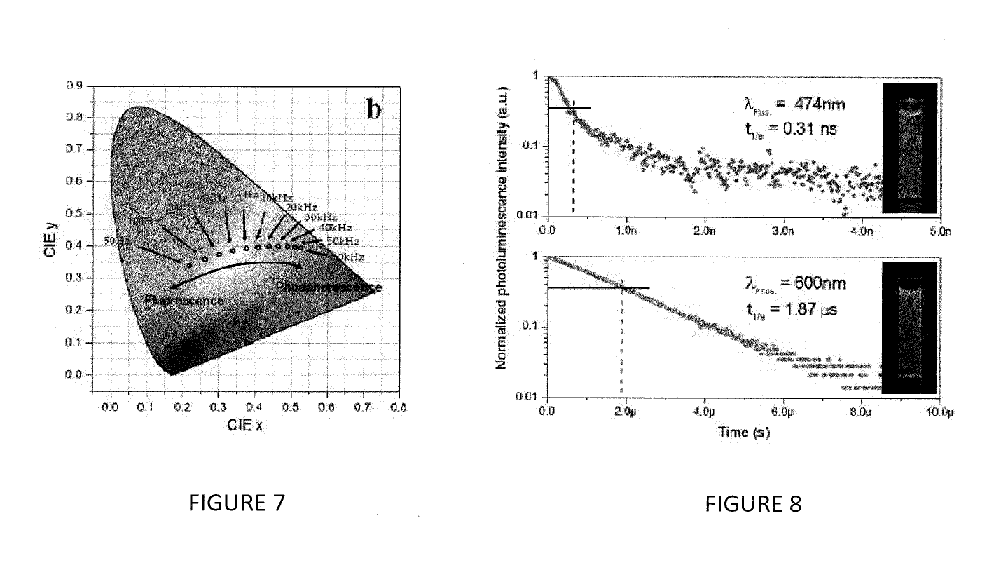

Variance of emitted wavelength with alternating current voltage frequency can permit tuning of the electroluminescent device to the desired region of the CIE color space. As illustrated in FIG. 7, chromaticity of the emitted light varies from bluish-green to orange as alternating current voltage frequency is increased from 50 Hz to 60 kHz. In more concrete terms, color coordinates of the emitted light vary from (0.23, 0.34) to (0.53, 0.4) as alternating current voltage frequency is increased from 50 Hz to 60 kHz.

In alternative embodiments, red, orange and/or yellow singlet emitting species can be employed in the singlet emitting layer and green and/or blue phosphorescent species, such as 4-F-FIrpic, 4-Cl-FIrpic and 4-Br-FIrpic, can be used in the triplet emitting layer. In such embodiments, the wavelength of emitted light can be inversely proportional to the frequency of the applied alternating current voltage. Emission from the red, orange and/or yellow singlet species would dominate at lower VAC frequencies. As VAC frequency is increased, the emission blue-shifts due to increased emission from the triplet layer. Therefore, chromaticity of the emitted light may vary from red-orange to bluish-green as alternating current voltage frequency is increased from 50 Hz to 60 kHz.

In some embodiments, alternating current voltage frequencies employed for methods and electroluminescent devices described herein can be selected from Table XII.

```
TABLE XII
Alternating Current Voltage Frequencies
  10 Hz-100 kHz
  10 kHz-100 kHz
  10 Hz-100 Hz
20 kHz-80 kHz
30 kHz-50 kHz
30 kHz-60 kHz
```

Electroluminescent devices suitable for use in methods of generating light can have any construction and/or properties described in Section I herein, including that of the electroluminescent devices illustrated in FIGS. 1-4. Further, methods of generating light described herein, in some embodiments, produce power and current efficiencies and luminance values listed in Table XI of Section I.

These and other embodiments are further illustrated in the following non-limiting example.

### Example 1—Electroluminescent Devices

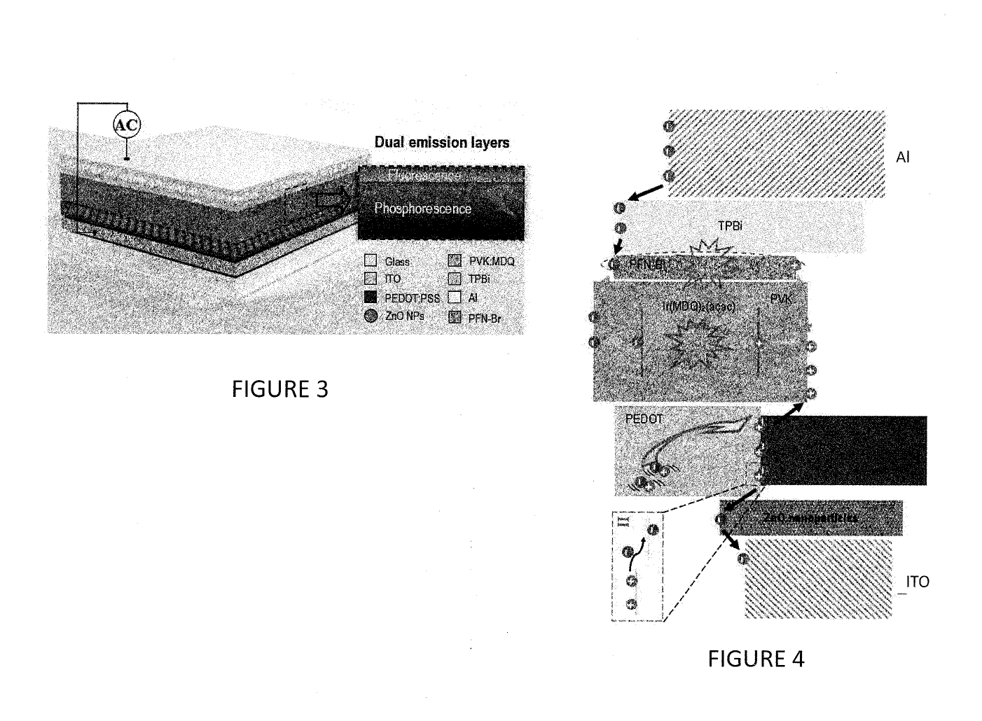

A first type of electroluminescent device (EL1) was fabricated as follows. EL1 devices were built on a 2.54 cm×2.54 cm glass substrate pre-coated with 140 nm thick layer of ITO having a sheet resistance ˜10Ω/□. These ITO glass substrate are cleaned in an ultrasonic bath with acetone followed by methanol and isopropanol for 1 hour each, and then dry-cleaned for 30 min by exposure to an UV-ozone ambient. To efficiently control the carriers transport under AC driving, PEDOT: PSS doped with 18 wt % ZnO NPs (˜35 nm) was spun onto the substrate to form a gate and hole dopant layer. As to the light emitting assembly, a layer of PVK (or PFN-DOF) with 3 wt % Ir(MDQ)₂(acac) was spin-coated using 10 mg/mL (or 5 mg/mL) in chlorobenzene (or toluene) at 2000 rpm, followed by baking at 100° C. for 30 min. The singlet emission layer was obtained by spin coating the 5 mg/mL, 8 mg/mL, or 10 mg/mL of PFN-Br blend in methanol at 3000 rpm and dried at 100° C. for 20 min. A 24 mg/mL electron-transport material (TPBi) was dissolved in formic acid: DI water (FA:H₂O=3:1) mixture and spun cast onto the EML at a spin speed of 4000 rpm followed by drying at 120° C. for 30 min. The top Al electrode was deposited by thermal evaporation through a shadow mask with 0.15 cm² opening. The structure of EL1 is represented schematically in FIG. 3. In addition, FIG. 4 illustrates schematically the movement of carriers through the structure of EL1.

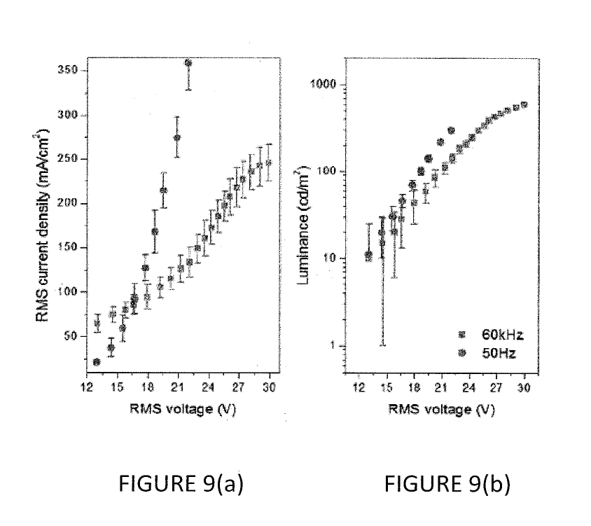

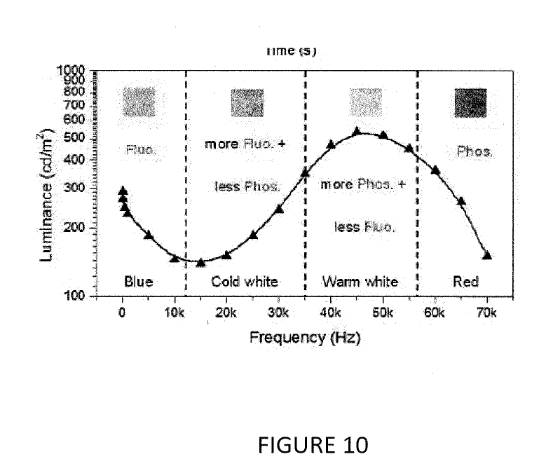

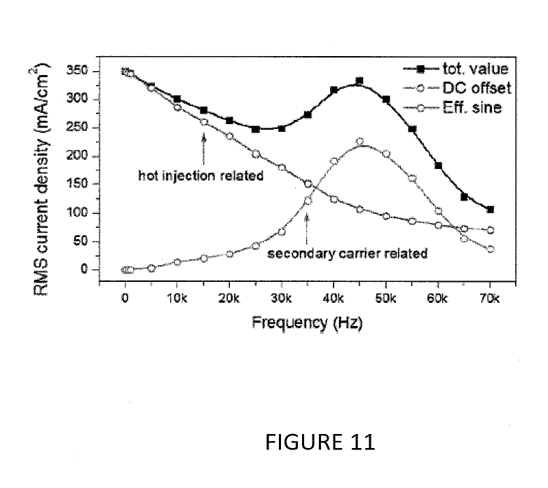

An alternating current voltage (VAC) was applied to ELL wherein the frequency of the VAC was varied. FIG. 7 illustrates the 1931 CIE Chromaticity Diagram coordinates for EL1 at different VAC frequencies. The lifetimes of short-lived blue fluorescence and long-lived red phosphorescence are given in FIG. 8 for 0.31 ns and 1.87 us respectively. Plus, Jᵣₘₛ-L-Vᵣₘₛ characteristics at low frequency (50 Hz) and high frequency (60,000 Hz) are shown in FIGS. 9(a) and 9(b) in which the maximum brightness, 360 cd/m² in blue and 600 cd/m² in red, are of the order necessary for devices for personal display use for instance. The luminance-frequency characteristic of the color tunable AC-OEL device is shown in FIG. 10. Corresponding to the singlet-triplet heterojunction shift, the frequency characteristics are shown with current density in FIG. 11. Analyzing the frequencies below 10,000 Hz first, it is noted that low frequencies lead to dominant hot carrier injection, since the device under low frequency driving can act more like a diode in forward and reverse bias.

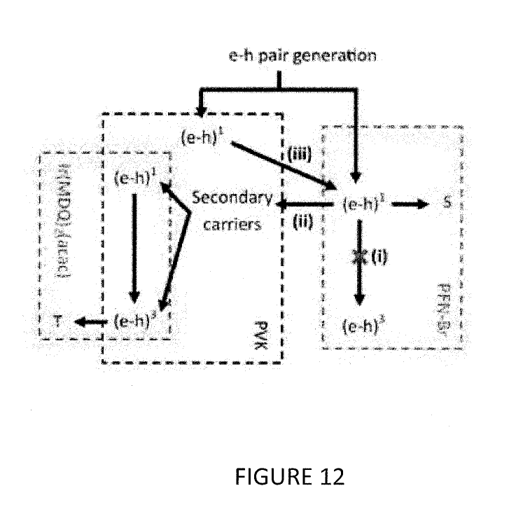

At higher frequencies, the current density consists of a sine wave and a DC offset, essentially reflecting both displacement of direct current injection and secondary charge current respectively. The DC offset component of the current through the device starts at a very low level (13.8 mA/cm²) at 10,000 Hz and then increases to 226.1 mA/cm² at 45,000 Hz. This result illustrates that electric field above 20,000 Hz applied on the capacitive device is sufficient to generate a magnetic field strong enough to yield secondary charge diffusion as suggested above. The stronger AC magnetic field suppresses ISC between singlet-state and triplet-state electron-hole pairs in the PFN-Br, resulting in population enhancement of singlet electron-hole pairs at the singlet-triplet interface. The elevated singlet-triplet ratio promotes the generation of secondary charge carriers. The hopping transport of secondary electrons and holes in the organic semiconductor is acutely tied to the generation of radical triplet excitons in Ir(MDQ)₂(acac). FIG. 12 illustrated the overall energy transfer at the singlet-triplet layer heterojunction for such populations. There are three processes need to address: (i) ISC of electron-hole pairs in PFN-Br is magnetic field sensitive; (ii) Accumulated singlet-spin electron-hole pairs are dissociated into diffusive secondary carriers with the assistance of Br ions; (iii) The energy transfer of electron-hole pairs between PVK and PFN-Br is efficient and one-way accessible.

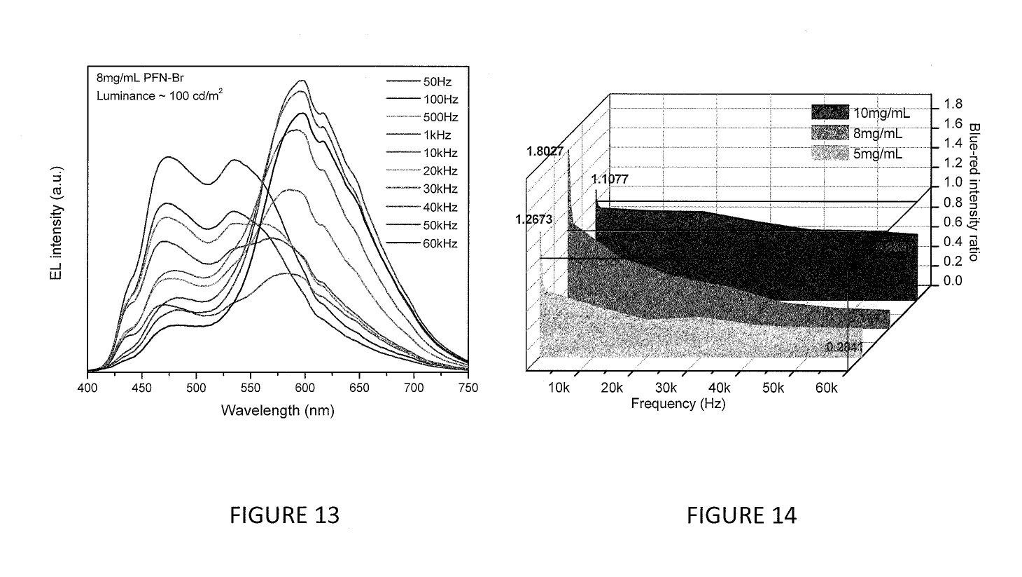

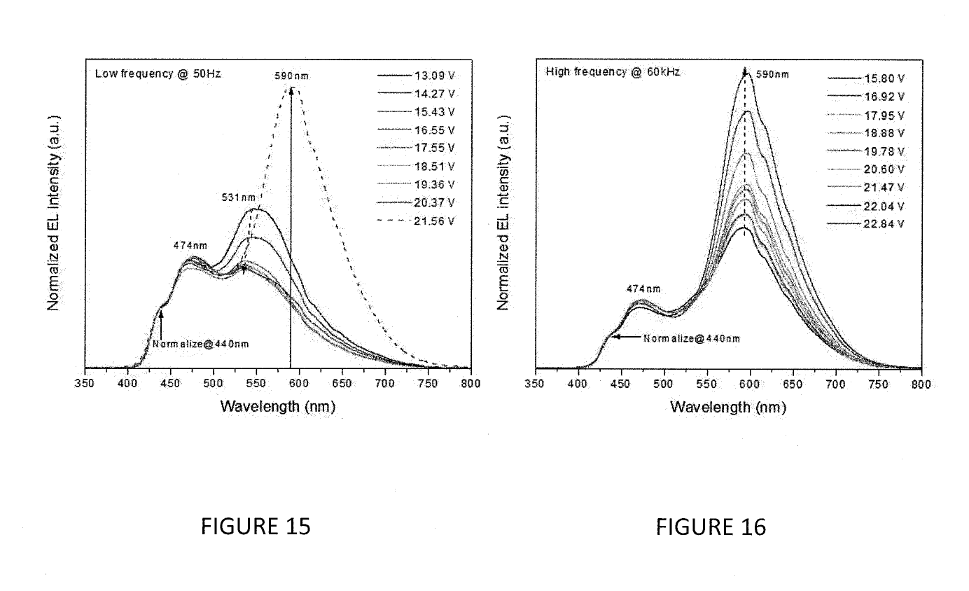

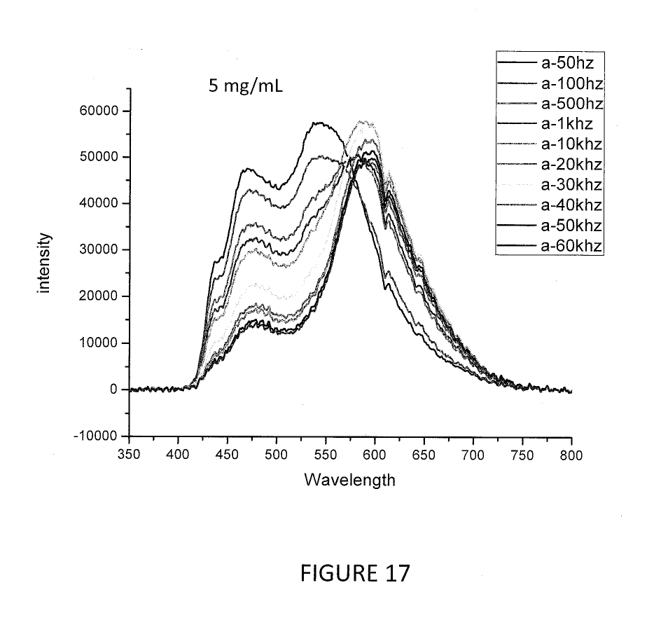

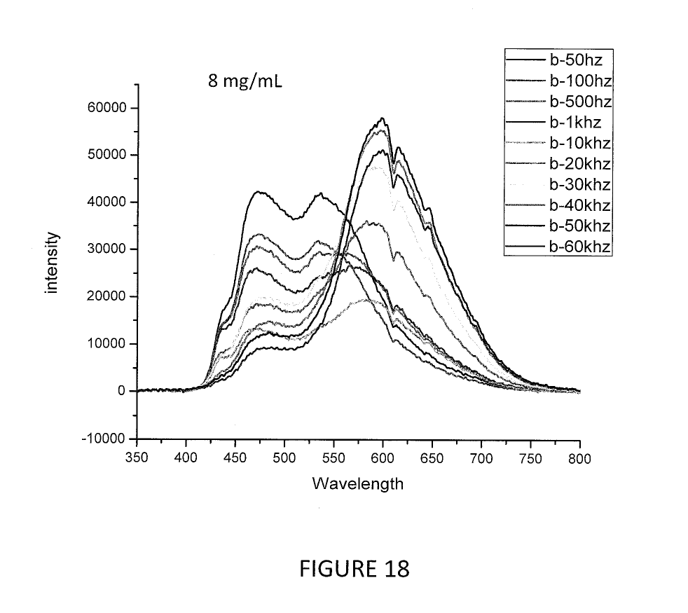

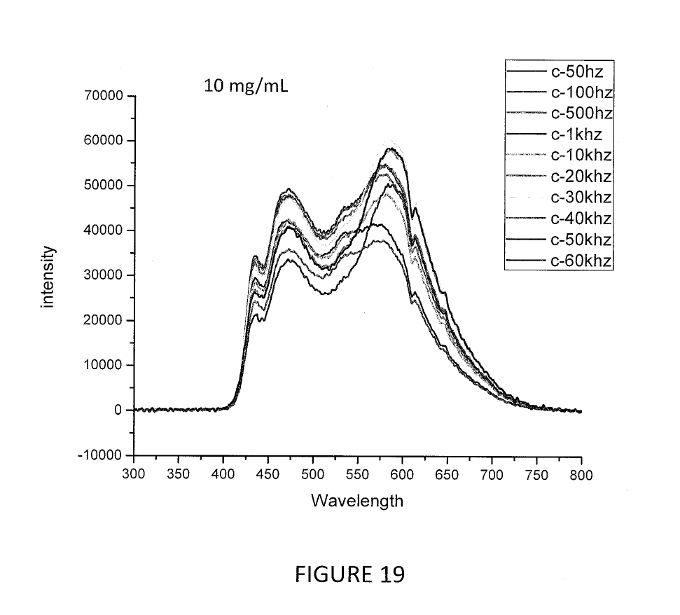

FIG. 13 illustrates electroluminescence intensity versus wavelength for EL1 at various VAC frequencies. As illustrated in FIG. 13, emission from the light emitting assembly red-shifted to higher wavelengths with increasing VAC frequency indicating greater emission from the triplet emitter phase. FIG. 14 illustrates the blue-red intensity ratio versus VAC frequency for EL1-type devices formed from different amounts of PFN-Br. FIGS. 15 and 16 illustrate normalized EL intensity versus wavelength for EL1 at various voltages at low VAC frequency (FIG. 12, 50 Hz) and high VAC frequency (FIG. 13, 60 kHz). FIGS. 17-19 illustrate EL intensity versus wavelength for EL1 at various VAC frequencies for different amounts of PFN-Br used in the singlet light emitting layer (FIG. 17, 5 mg/mL; FIG. 18, 8 mg/mL; FIG. 19, 10 mg/mL).

Additional embodiments are described in the attached Appendix.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the invention.

1. An electroluminescent device comprising:
a first electrode and a second electrode;
a light emitting assembly positioned between the first electrode and the second electrode, the light emitting assembly including a triplet light emitting layer and a singlet light emitting layer
wherein emission from the light emitting assembly varies on the CIE color space as a function of alternating current voltage frequency applied to the first and second electrodes.

2. The electroluminescent device of claim 1, wherein intensity of emission from the singlet light emitting layer compared to the triplet light emitting layer varies as a function of alternating current voltage frequency applied to the first and second electrodes.

3. The electroluminescent device of claim 2, wherein the device exhibits greater emission from the singlet light emitting layer at alternating current voltage frequencies less than 1 kHz relative to the triplet light emitting layer.

4. The electroluminescent device of claim 2, wherein the device exhibits greater emission from the triplet light emitting layer at alternating current voltage frequencies greater than 1 kHz relative to the singlet light emitting layer.

5. The electroluminescent device of claim 1 further comprising:
a current injection gate positioned between the first electrode and the light emitting assembly or between the second electrode and the light emitting assembly,
wherein the current injection gate comprises a semiconductor layer of electronic structure restricting injected current flow from the first or second electrode through the semiconductor layer as a function of alternating current voltage frequency applied to the first and second electrodes.

6. The electroluminescent device of claim 5, wherein injected current flow through the semiconductor layer of the gate decreases with increasing frequency of the applied alternating current voltage.

7. The electroluminescent device of claim 5 further comprising an electron dopant layer is adjacent to the singlet light emitting layer and a hole dopant layer is adjacent to the triplet light emitting layer.

8. The electroluminescent device of claim 1 further comprising a dielectric layer disposed between the light emitting assembly and the first electrode or between the light emitting assembly and the second electrode.

9. The electroluminescent device of claim 1, wherein the first electrode, second electrode or both are radiation transmissive.

10. The electroluminescent device of claim 1, wherein the triplet light emitting layer comprises one or more triplet emitting species dispersed in a host material phase.

11. The electroluminescent device of claim 10, wherein the triplet light emitting layer further comprises a nanoparticle phase.

12. The electroluminescent device of claim 11, wherein the nanoparticle phase comprises carbon nanoparticles, inorganic nanoparticles or mixtures thereof.

13. The electroluminescent device of claim 10, wherein the host material phase is formed from a fluorescing polymeric material.

14. The electroluminescent device of claim 10, wherein the triplet emitting species comprises a transition metal complex.

15. The electroluminescent device of claim 1, wherein the singlet light emitting layer is formed of one or more polymeric materials.

16. The electroluminescent device of claim 15, wherein the singlet light emitting layer comprises one or more polyfluorenes.

17. The electroluminescent device of claim 15, wherein the singlet light emitting layer has an emission profile in the blue or green region of the 1931 CIE Chromaticity Diagram.

18. The electroluminescent device of claim 17, wherein the triplet light emitting layer emitting layer has an emission profile in red light region of the 1931 CIE Chromaticity Diagram.

19. The electroluminescent device of claim 1, wherein the electroluminescent device is an OLED device.

20. The electroluminescent device of claim 1, wherein the electroluminescent device is a field-induced device.
